(19) United States
(12) Patent Application Publication
(10) Pub. No.: US 2026/0280516 A1
(43) Pub. Date: Sep. 17, 2026

(54) LONGITUDINAL MODE SURFACE ACOUSTIC WAVE RESONATOR WITH ENERGY CONFINEMENT LAYER AND A METHOD OF MANUFACTURE

(71) Applicant: RF360 Singapore Pte. Ltd., Singapore (SG)

(72) Inventors: Soeren Zimmermann, München (DE); Willi Aigner, Moosinning (DE); Ralph Durner, München (DE)

(21) Appl. No.: 19/078,118

(22) Filed: Mar. 12, 2025

(51) Int. Cl. H03H 9/02; H03H 3/08; H03H 9/25

(52) U.S. Cl. CPC H03H 9/02866; H03H 3/08; H03H 9/02559; H03H 9/02834; H03H 9/25

(57) ABSTRACT

A high-velocity layer between the piezoelectric layer and the carrier substrate in a microacoustic surface acoustic wave (SAW) resonator reflects irradiated energy back to the piezoelectric layer to improve the resonance quality factors. Such a microacoustic SAW resonator operated in the longitudinal mode allows higher resonant frequencies than operation in shear horizontal (SH) and Rayleigh modes without a corresponding reduction in pitch size of an interdigitated transducer (IDT) electrode structure on the piezoelectric layer. In some examples, performance of the microacoustic SAW resonator in longitudinal mode may be optimized by the IDT electrode structure having a thickness in a range based on a wavelength of the resonant frequency.

### TECHNICAL FIELD

This disclosure relates generally to wireless transceivers and other components that employ filters and, more specifically, to a microacoustic resonator that employs a longitudinal mode with a high velocity layer to reduce energy losses into a carrier substrate.

### BACKGROUND

Electronic devices use radio-frequency (RF) signals to communicate information. These radio-frequency signals enable users to talk with friends, download information, share pictures, remotely control household devices, and receive global positioning information. To transmit or receive the radio-frequency signals within a given frequency band, the electronic device may use filters to pass signals within the frequency band and to suppress (e.g., attenuate) jammers or noise at frequencies outside of the frequency band. It can be challenging, however, to design a filter that provides filtering for radio-frequency applications, including those that utilize frequencies above 3 gigahertz (GHz), such as for the 5G and higher generations of cellular network technology.

### SUMMARY

An apparatus is disclosed that implements a longitudinal mode surface acoustic wave resonator with an energy confinement layer. Certain crystalline orientations of a piezoelectric material enable a piezoelectric layer to be excited in a longitudinal (e.g., leaky) mode, but a microacoustic surface acoustic wave (SAW) resonator comprising such a piezoelectric layer is subject to energy loss in this longitudinal mode by irradiation into a carrier substrate. In an exemplary aspect, a high-velocity layer between the piezoelectric layer and the carrier substrate in a microacoustic SAW resonator reflects irradiated energy back to the piezoelectric layer to improve the resonance quality factors. Such a microacoustic SAW resonator operated in the longitudinal mode allows higher resonant frequencies than operation in shear horizontal (SH) and Rayleigh modes without a corresponding reduction in pitch size of an interdigitated transducer (IDT) electrode structure on the piezoelectric layer. In some examples, performance of the microacoustic SAW resonator in longitudinal mode may be optimized by the IDT electrode structure having a thickness in a range based on a wavelength of the resonant frequency.

In an example aspect, a microacoustic SAW resonator is disclosed. The microacoustic resonator includes a piezoelectric layer having a crystallographic orientation operative to excite a longitudinal mode having a resonant frequency; a substrate; a first layer between, in a first direction, the piezoelectric layer and the substrate and including a first material having a first thickness equal to or greater than a first wavelength of the longitudinal mode at the resonant frequency and a first acoustic velocity higher than a second acoustic velocity of the piezoelectric layer; and an electrode structure including fingers on a first surface of the piezoelectric layer.

In an example aspect, an apparatus is disclosed. The apparatus includes a transceiver circuit comprising a microacoustic SAW resonator, including a piezoelectric layer having a crystallographic orientation operative to excite a longitudinal mode having a resonant frequency; a substrate; a first layer between, in a first direction, the piezoelectric layer and the substrate and including a first material having a first thickness equal to or greater than a first wavelength of the longitudinal mode at the resonant frequency and a first acoustic velocity higher than a second acoustic velocity of the piezoelectric layer; and an electrode structure including fingers on a first surface of the piezoelectric layer. The apparatus includes an antenna coupled to the transceiver circuit.

In an example aspect, a method for fabricating a microacoustic SAW resonator is disclosed. The method includes forming a piezoelectric layer having a crystallographic orientation operative to excite a longitudinal mode having a resonant frequency; forming a substrate; forming a first layer between, in a first direction, the piezoelectric layer and the substrate and including a first material having a first thickness equal to or greater than a first wavelength of the longitudinal mode at the resonant frequency and a first acoustic velocity higher than a second acoustic velocity of the piezoelectric layer; and forming an electrode structure including fingers on a first surface of the piezoelectric layer.

### BRIEF DESCRIPTION OF DRAWINGS

FIG. 1 illustrates an example operating environment for operating a microacoustic SAW resonator operating in a longitudinal mode and including a high-velocity layer to confine irradiated acoustic energy;

FIG. 2 illustrates an example wireless transceiver including at least one microacoustic SAW resonator operating in a longitudinal mode and including a high-velocity layer to confine irradiated acoustic energy;

FIG. 3-1 illustrates example components of a microacoustic SAW resonator operating in a longitudinal mode and including a high-velocity layer to confine irradiated acoustic energy;

FIG. 3-2 illustrates example Euler angles that define an orientation of a piezoelectric layer of a microacoustic SAW resonator operating in a longitudinal mode and including a high-velocity layer to confine irradiated acoustic energy;

FIGS. 4A-4C illustrate views of example implementations of a microacoustic SAW resonator operating in a longitudinal mode and including a high-velocity layer to confine irradiated acoustic energy;

FIG. 5 is a flowchart illustrating a process of fabricating a microacoustic SAW resonator operating in a longitudinal mode and including a high-velocity layer to confine irradiated acoustic energy;

FIG. 6 is a block diagram of an exemplary wireless communication device that includes a microacoustic SAW resonator operating in a longitudinal mode and including a high-velocity layer to confine irradiated acoustic energy; and

FIG. 7 is a block diagram of an exemplary processor-based system that can include a microacoustic SAW resonator operating in a longitudinal mode and including a high-velocity layer to confine irradiated acoustic energy.

### DETAILED DESCRIPTION

An apparatus is disclosed that implements a longitudinal mode surface acoustic wave resonator with an energy confinement layer. Certain crystalline orientations of a piezoelectric material enable a piezoelectric layer to be excited in a longitudinal (e.g., leaky) mode, but a microacoustic surface acoustic wave (SAW) resonator comprising such a piezoelectric layer is subject to energy loss in this longitudinal mode by irradiation into a carrier substrate. In an exemplary aspect, a high-velocity layer between the piezoelectric layer and the carrier substrate in a microacoustic SAW resonator reflects irradiated energy back to the piezoelectric layer to improve the resonance quality factors. Such a microacoustic SAW resonator operated in the longitudinal mode allows higher resonance frequencies than operation in shear horizontal (SH) and Rayleigh modes without a corresponding reduction in pitch size of an interdigitated transducer (IDT) electrode structure on the piezoelectric layer. In some examples, performance of the microacoustic SAW resonator in longitudinal mode may be optimized by the IDT electrode structure having a thickness in a range based on a wavelength of the resonant frequency.

An electronic device may use filters to pass radio-frequency signals transmitted or received within a given frequency and to suppress (e.g., attenuate) jammers or noise-having frequencies outside of the frequency band. Electroacoustic devices (e.g., “acoustic filters”) can be used to filter high-frequency signals in many applications, such as those with frequencies that are greater than 100 megahertz (MHz). An acoustic filter is tuned to pass certain frequencies (e.g., frequencies within its passband) and attenuate other frequencies (e.g., frequencies that are outside of its passband). Using a piezoelectric material, the acoustic filter operates by transforming an electrical signal wave that is applied to an electrical conductor into an acoustic wave (e.g., an acoustic signal wave) that forms across the piezoelectric material. The acoustic wave is then converted back into an electrical filtered signal. The acoustic filter can include an electrode structure that transforms or converts between the electromagnetic and acoustic waves.

The acoustic wave features a velocity having a magnitude that is significantly less than that of a velocity of the electromagnetic wave. Generally, the magnitude of the propagation velocity of a wave is proportional to a size of a wavelength of the wave. Consequently, after conversion of the electrical signal wave into the acoustic signal wave, the wavelength of the acoustic signal wave is significantly smaller than the wavelength of the electrical signal wave. The resulting smaller wavelength of the acoustic signal wave enables filtering to be performed using a smaller filter device. This permits acoustic filters to be used in space-constrained devices, including portable electronic devices such as cellular phones. These acoustic filters can be referred to as microacoustic filters.

It can be challenging to design a microacoustic filter that can provide filtering for higher frequencies, such as those used with Wi-Fi® at 2.4 gigahertz (GHz) and higher, 3 GHz to 7 GHz frequencies, and frequencies between 7 and 18 GHz and higher. In particular, it can be challenging to design a filter that is affordable, can realize a target level of performance in terms of resonance quality factors, electromechanical coupling, temperature coefficient of frequency (TCF), power durability, insertion loss, and spurious-mode suppression, and operate at the frequencies employed in cell phones and other types of communications now and in the future.

To address these challenges, some techniques implement SAW microacoustic filters excited in longitudinal mode (also known as longitudinal leaky mode). Compared to other types of microacoustic filters, such as SAW filters employing shear horizontal (SH) or Rayleigh modes, the longitudinal-mode microacoustic filters can realize a higher frequency of operation without a corresponding change in pitch of the fingers of an electronic IDT structure. Resonance quality factors (Q factors), which relate to energy loss in the microacoustic resonators, can be negatively impacted by irradiation of energy through a carrier substrate. In particular, current designs can experience degraded quality factors, power durability issues, temperature instability, and spurious-mode excitation.

To provide certain performance improvements, techniques for implementing a microacoustic SAW resonator with a high-velocity layer to reflect energy irradiated from a piezoelectric layer toward the carrier substrate back to the piezoelectric layer are disclosed. A large portion of the acoustic energy irradiated from the piezoelectric layer is unable to pass through a high-velocity layer having a thickness in a defined range (e.g., above a defined minimum range) and having a high quality crystal structure providing a high level of stiffness. In this manner, energy irradiated from the piezoelectric layer on a first side of the high-velocity layer is confined to the first side of the high-velocity layer (e.g., within the piezoelectric layer and other layers, if any, of the microacoustic resonator on the first side of the high-velocity layer). Such confinement allows the microacoustic resonator to achieve high quality factors. One or more additional layers may be included to maintain low overall TCFs.

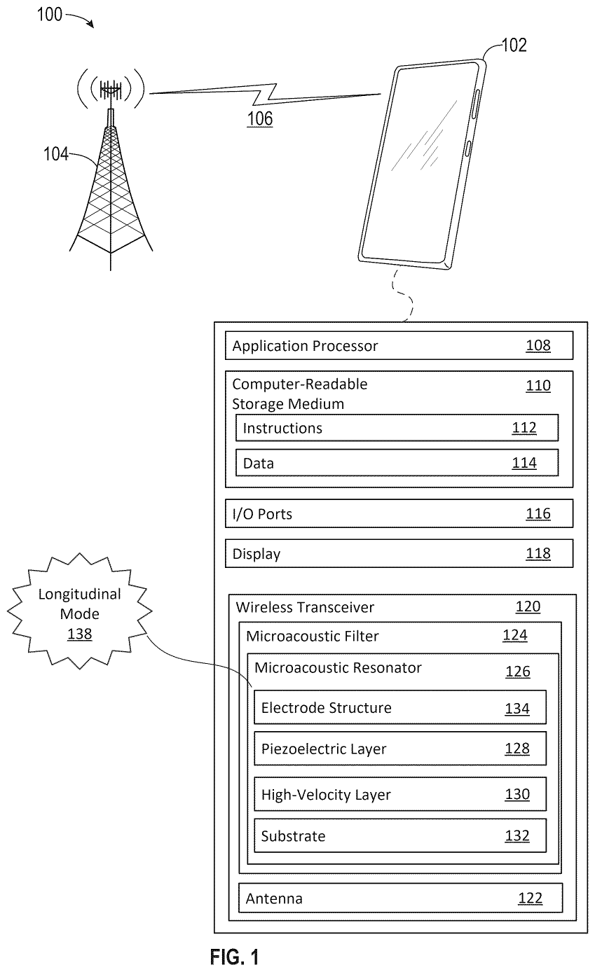

FIG. 1 illustrates an example environment 100 for operating a microacoustic SAW resonator in longitudinal mode with a high-velocity layer for energy confinement. In the environment 100, a computing device 102 communicates with a base station 104 through a wireless communication link 106 (wireless link 106). In this example, the computing device 102 is depicted as a smartphone. However, the computing device 102 can be implemented as any suitable computing or electronic device, such as a modem, a cellular base station, a broadband router, an access point, a cellular phone, a gaming device, a navigation device, a media device, a laptop computer, a desktop computer, a tablet computer, a wearable computer, a server, a network-attached storage (NAS) device, a smart appliance or other internet of things (IoT) device, a medical device, a vehicle-based communication system, a radar, a radio apparatus, and so forth. Use of a microacoustic resonator is not limited to acoustic filters for wireless communication as a microacoustic filter can be applied in any technological field where such filtering is useful.

The base station 104 communicates with the computing device 102 via the wireless link 106, which can be implemented as any suitable type of wireless link. Although depicted as a tower of a cellular network, the base station 104 can represent or be implemented as another device, such as a satellite, a server device, a terrestrial television broadcast tower, an access point, a peer-to-peer device, a mesh network node, and so forth. Therefore, the computing device 102 may communicate with the base station 104 or another device via a wireless connection.

The wireless link 106 can include a downlink of data or control information communicated from the base station 104 to the computing device 102, an uplink of other data or control information communicated from the computing device 102 to the base station 104, or both a downlink and an uplink. The wireless link 106 can be implemented using any suitable communication protocol or standard, such as 2nd-generation (2G), 3rd-generation (3G), 4th-generation (4G), 5th-generation (5G), or 6th-generation (6G) cellular; IEEE 802.11 (e.g., Wi-Fi®); IEEE 802.15 (e.g., Bluetooth®); IEEE 802.16 (e.g., WiMAX®); and so forth. In some implementations, the wireless link 106 may wirelessly provide power and the base station 104 or the computing device 102 may comprise a power source.

As shown, the computing device 102 includes an application processor 108 and a computer-readable storage medium 110 (CRM 110). The application processor 108 can include any type of processor, such as a multi-core processor, that executes processor-executable code stored by the CRM 110. The CRM 110 can include any suitable type of data storage media, such as volatile memory (e.g., random access memory (RAM)), non-volatile memory (e.g., Flash memory), optical media, magnetic media (e.g., disk), and so forth. In the context of this disclosure, the CRM 110 is implemented to store instructions 112, data 114, and other information of the computing device 102, and thus does not include transitory propagating signals or carrier waves.

The computing device 102 can also include input/output ports 116 (I/O ports 116) and a display 118. The I/O ports 116 enable data exchanges or interaction with other devices, networks, users, or the environment. The I/O ports 116 can include serial ports (e.g., universal serial bus (USB) ports), parallel ports, audio ports, infrared (IR) ports, user interface ports such as a touchscreen, and so forth. The display 118 presents graphics of the computing device 102, such as a user interface associated with an operating system, program, or application. Alternatively or additionally, the display 118 can be implemented as a display port or virtual interface through which graphical content of the computing device 102 is presented.

A wireless transceiver 120 of the computing device 102 provides connectivity to respective networks and other electronic devices connected therewith. The wireless transceiver 120 can facilitate communication over any suitable type of wireless network, such as a wireless local area network (WLAN), peer-to-peer (P2P) network, mesh network, cellular network, ultra-wideband (UWB) network, wireless wide-area-network (WWAN), and/or wireless personal-area-network (WPAN). In the context of the example environment 100, the wireless transceiver 120 enables the computing device 102 to communicate with the base station 104 and networks connected therewith. However, the wireless transceiver 120 can also enable the computing device 102 to communicate “directly” with other devices or networks.

The wireless transceiver 120 includes circuitry and logic for transmitting and receiving communication signals via an antenna 122. Components of the wireless transceiver 120 can include amplifiers, switches, mixers, analog-to-digital converters, filters, and so forth for conditioning the communication signals (e.g., for generating or processing signals). The wireless transceiver 120 can also include logic to perform in-phase/quadrature (I/Q) operations, such as synthesis, encoding, modulation, decoding, demodulation, and so forth. In some cases, components of the wireless transceiver 120 are implemented as separate transmitter and receiver entities. Additionally or alternatively, the wireless transceiver 120 can be realized using multiple or different sections to implement respective transmitting and receiving operations (e.g., separate transmit and receive chains). In general, the wireless transceiver 120 processes data and/or signals associated with communicating data of the computing device 102 over the antenna 122.

In the example shown in FIG. 1, the wireless transceiver 120 includes at least one microacoustic filter 124 including at least one microacoustic SAW resonator (also referred to herein as “microacoustic resonator”) 126, which may operate in a longitudinal mode. In some implementations, the wireless transceiver 120 includes multiple microacoustic filters 124, which can be formed from microacoustic resonators 126 arranged in series, in parallel, in a ladder structure, in a lattice structure, or some combination thereof. The microacoustic resonator 126 includes a piezoelectric layer 128, a high-velocity layer 130, and a substrate 132. The microacoustic resonator 126 also includes an electrode structure 134 on the piezoelectric layer 128. It is possible to implement the substrate 132 as a single layer or as multiple layers.

Although the microacoustic resonator 126 can be any type of microacoustic resonator, the piezoelectric layer 128 is excited in a longitudinal mode 138 and the microacoustic resonator 126 includes the high-velocity layer 130 between the piezoelectric layer 128 and the carrier substrate 132 to confine acoustic energy irradiated toward the substrate 132 to reduce energy losses through the substrate 132. The longitudinal mode 138 may also be known as a longitudinal leaky mode 138.

The piezoelectric layer 128 has a crystalline structure operative to excite the longitudinal mode 138. Longitudinal mode SAW resonators are beneficial in high-frequency SAW devices because their phase velocity is 1.5-2 times higher than that of conventional shear horizontal (SH) mode SAW resonators. However, a significant challenge of longitudinal mode SAW devices is large attenuation and a low Q factor due to the radiation of some types of bulk waves towards the carrier substrate 132. Including the high-velocity layer 130 having a higher phase velocity in a longitudinal mode SAW resonator significantly reduces propagation of the bulk waves and corresponding energy losses into the carrier substrate 132, providing a much higher Q factor.

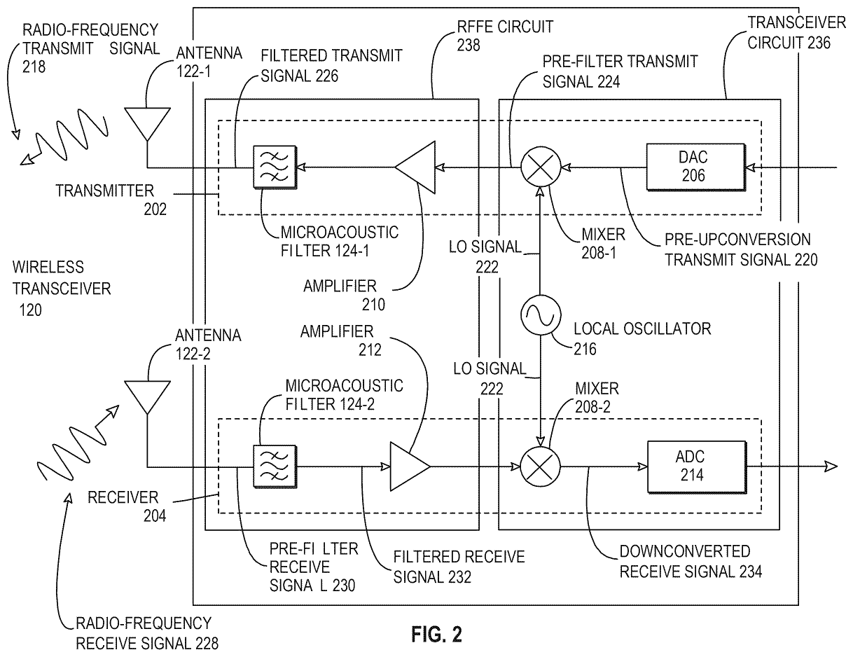

With the above improvements, the microacoustic filter 124 can be designed to support frequency ranges above 3 GHz, including frequencies between approximately 3 and 20 GHz. For example, the microacoustic resonator 126 can be designed to have a resonance frequency between approximately 4 and 18 GHz, between approximately 4.5 and 7.5 GHz, or equal to approximately 4, 5, 6, 7, 8, 10, 13, 15, 17, or 20 GHz. In general, the term “approximately” can mean that any of the frequencies can be within ±10% of a specified value or less (e.g., within ±5%, ±3%, or ±2% of a specified value). The microacoustic filter 124 is further described with respect to FIG. 2.

FIG. 2 illustrates an example wireless transceiver 120. In the depicted configuration, the wireless transceiver 120 includes a transmitter 202 and a receiver 204, which are respectively coupled to a first antenna 122-1 and a second antenna 122-2. In other implementations, the transmitter 202 and the receiver 204 can be connected to a same antenna through a duplexer (not shown). The transmitter 202 is shown to include at least one digital-to-analog converter 206 (DAC 206), at least one first mixer 208-1, at least one amplifier 210 (e.g., a power amplifier), and at least one first microacoustic filter 124-1. The receiver 204 includes at least one second microacoustic filter 124-2, at least one amplifier 212 (e.g., a low-noise amplifier), at least one second mixer 208-2, and at least one analog-to-digital converter 214 (ADC 214). The first mixer 208-1 and the second mixer 208-2 are coupled to a local oscillator 216. Although not explicitly shown, the digital-to-analog converter 206 of the transmitter 202 and the analog-to-digital converter 214 of the receiver 204 can be coupled to the application processor 108 (of FIG. 1) or another processor associated with the wireless transceiver 120 (e.g., a modem).

In some implementations, the wireless transceiver 120 is implemented using multiple circuits (e.g., multiple integrated circuits), such as a transceiver circuit 236 and a radio-frequency front-end (RFFE) circuit 238. As such, the components that form the transmitter 202 and the receiver 204 are distributed across these circuits. As shown in FIG. 2, the transceiver circuit 236 includes the digital-to-analog converter 206 of the transmitter 202, the mixer 208-1 of the transmitter 202, the mixer 208-2 of the receiver 204, and the analog-to-digital converter 214 of the receiver 204. In other implementations, the digital-to-analog converter 206 and the analog-to-digital converter 214 can be implemented on another separate circuit that includes the application processor 108 or the modem. The radio-frequency front-end circuit 238 includes the amplifier 210 of the transmitter 202, the microacoustic filter 124-1 of the transmitter 202, the microacoustic filter 124-2 of the receiver 204, and the amplifier 212 of the receiver 204.

During transmission, the transmitter 202 generates a radio-frequency transmit signal 218, which is transmitted using the antenna 122-1. To generate the radio-frequency transmit signal 218, the digital-to-analog converter 206 provides a pre-upconversion transmit signal 220 to the first mixer 208-1. The pre-upconversion transmit signal 220 can be a baseband signal or an intermediate-frequency signal. The first mixer 208-1 upconverts the pre-upconversion transmit signal 220 using a local oscillator (LO) signal 222 provided by the local oscillator 216. The first mixer 208-1 generates an upconverted signal, which is referred to as a pre-filter transmit signal 224. The pre-filter transmit signal 224 can be a radio-frequency signal and include some noise or unwanted frequencies, such as a harmonic frequency. The amplifier 210 amplifies the pre-filter transmit signal 224 and passes the amplified pre-filter transmit signal 224 to the first microacoustic filter 124-1.

The first microacoustic filter 124-1 filters the amplified pre-filter transmit signal 224 to generate a filtered transmit signal 226. As part of the filtering process, the first microacoustic filter 124-1 attenuates the noise or unwanted frequencies within the pre-filter transmit signal 224. The transmitter 202 provides the filtered transmit signal 226 to the antenna 122-1 for transmission. The transmitted filtered transmit signal 226 is represented by the radio-frequency transmit signal 218.

During reception, the antenna 122-2 receives a radio-frequency receive signal 228 and passes the radio-frequency receive signal 228 to the receiver 204. The second microacoustic filter 124-2 accepts the received radio-frequency receive signal 228, which is represented by a pre-filter receive signal 230. The second microacoustic filter 124-2 filters any noise or unwanted frequencies within the pre-filter receive signal 230 to generate a filtered receive signal 232.

The amplifier 212 of the receiver 204 amplifies the filtered receive signal 232 and passes the amplified filtered receive signal 232 to the second mixer 208-2. The second mixer 208-2 downconverts the amplified filtered receive signal 232 using the LO signal 222 to generate the downconverted receive signal 234. The analog-to-digital converter 214 converts the downconverted receive signal 234 into a digital signal, which can be processed by the application processor 108 or another processor associated with the wireless transceiver 120 (e.g., the modem).

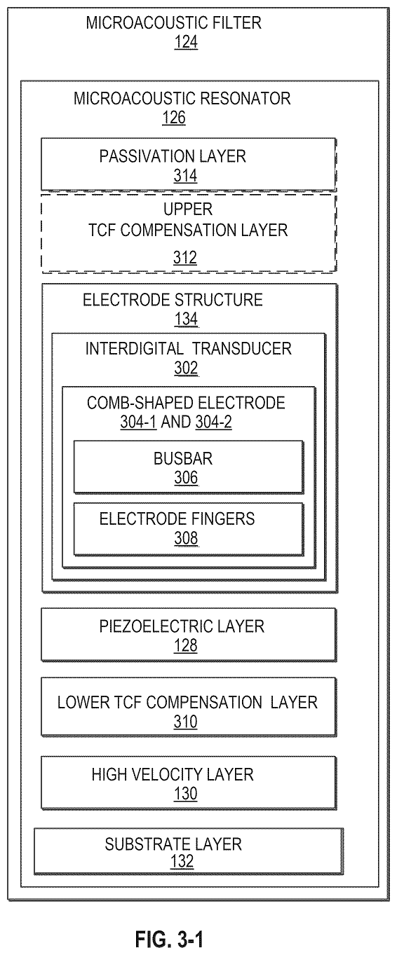

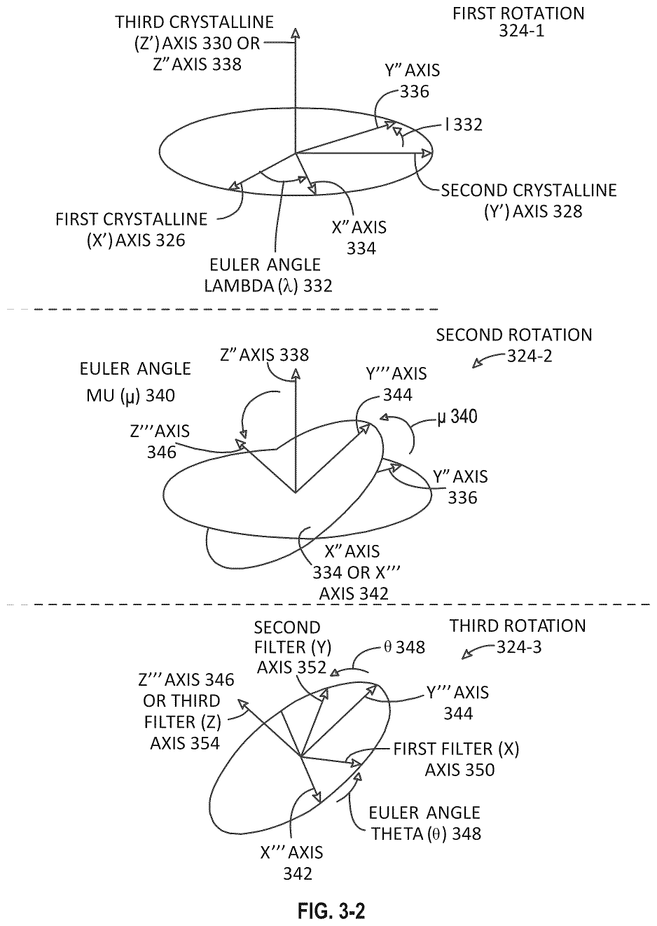

FIG. 2 illustrates one example configuration of the wireless transceiver 120. Other configurations of the wireless transceiver 120 can support multiple frequency bands and share an antenna 122 across multiple transceivers. One of ordinary skill in the art can appreciate the variety of other configurations for which microacoustic filters 124 may be included. For example, the microacoustic filters 124 can be integrated within duplexers or diplexers of the wireless transceiver 120. Example implementations of the microacoustic filter 124-1 or 124-2 are further described with respect to FIG. 3-1.

FIG. 3-1 illustrates example components of the microacoustic filter 124. In the depicted configuration, the microacoustic resonator 126 includes the piezoelectric layer 128 and the high-velocity layer 130. In example implementations, the piezoelectric layer 128 can be implemented using a variety of different materials that exhibit piezoelectric properties (e.g., can transfer mechanical energy into electrical energy or electrical energy into mechanical energy). Example types of material include lithium niobate (LiNbO₃), lithium tantalate (LiTaO₃), or some combination thereof. In general, the material that forms the piezoelectric layer 128 may have a crystalline structure. This crystalline structure is defined by an ordered arrangement of particles (e.g., atoms, ions, or molecules). The orientation of the crystalline structure of the piezoelectric layer 128 can be defined by Euler angles lambda (λ), mu (μ), and theta (θ).

In some aspects, the material and crystalline structure of the piezoelectric layer 128 are selected such that the longitudinal mode 138 can be laterally excited within the piezoelectric layer 128. Consider the following examples in which the piezoelectric layer 128 is formed using lithium niobate. In a first example implementation, the lithium niobate material is cut such that values of the Euler angles mu (μ) and lambda (λ) are each approximately 90° and a value of the Euler angle theta (θ) is approximately 42° (or at least one symmetrical equivalent thereof). In a second example implementation, the lithium niobate material is cut such that that a value of the Euler angle mu (μ) is approximately 0°, a value of the Euler angle lambda (λ) is approximately 32.5°, and a value of the Euler angle theta (θ) is approximately 90° (or at least one symmetrical equivalent thereof). In a third example implementation, the lithium niobate material is cut such that that a value of the Euler angle mu (μ) is approximately 0°, a value of the Euler angle lambda (λ) is approximately −50°, and a value of the Euler angle theta (θ) is approximately 50° (or at least one symmetrical equivalent thereof). In general, the term “approximately” can mean that any of the angles can be within ±10% of a specified value or less (e.g., within ±5%, ±3%, or ±2% of a specified value).

The electrode structure 134 comprises an electrically conductive material, such as metal, and can include one or more layers. The one or more layers can include one or more electrically conductive layers and can optionally include one or more adhesion layers. As an example, the electrically conductive layers can be composed of aluminum (Al), copper (Cu), silver (Ag), gold (Au), tungsten (W), silicon (Si), or some combination or alloyed version thereof. The adhesion layers can be composed of chromium (Cr), titanium (Ti), molybdenum (Mo), or some combination thereof.

The electrode structure 134 can include one or more interdigital transducers 302. The interdigital transducer 302 converts an electrical signal into an acoustic wave and converts the acoustic wave into a filtered electrical signal. The interdigital transducer 302 includes at least two comb-shaped electrodes 304-1 and 304-2. Each comb-shaped electrode 304-1 and 304-2 includes a busbar 306 (e.g., a conductive segment or rail) and multiple fingers 308 (e.g., electrode fingers) that extend from the busbar 306. Although not explicitly shown, the electrode structure 134 can also include two or more reflectors. In an example implementation, the interdigital transducer 302 may be arranged between two reflectors.

The longitudinal (“leaky”) mode is sensitive to the IDT thickness and low acoustic losses (i.e., high performance) are achieved within a suitable range of IDT thickness. This contrasts with the shear horizontal (SH) and Rayleigh modes, which are much less sensitive to changes in IDT thickness. The range 0.06-0.08 (e.g., 6% to 8%) of a wavelength (Λ) of the acoustic mode at resonance of the microacoustic resonator 126 is the suitable IDT thickness range for the longitudinal mode, where a high level of performance is achieved with an electrode structure 134 comprising an aluminum-based alloy (Al, Cu, Ti/Cr). In particular, higher performance is achieved in the range of 0.07-0.08 (e.g., 7% to 8%) of the wavelength (Λ), where the greater thickness provides a lower resistance.

The substrate layer 132 is composed of material that is non-conducting and provides isolation. Example materials include silicon (Si), silicon dioxide (SiO₂), silicon carbide (SiC), sapphire, glass, or some combination or doped version thereof. In some implementations, the substrate layer 132 is composed of multiple layers. The multiple layers can be formed using the same material or different materials.

The microacoustic SAW resonator 126 can include an optional lower TCF compensation layer 310 and/or an optional upper TCF layer 312 provided to offset a temperature coefficient of frequency (TCF) of the piezoelectric layer. The lower TCF compensation layer 310 is disposed between the piezoelectric layer 128 and the high velocity layer 130 and provides temperature compensation to enable the microacoustic resonator 126 to achieve a target temperature coefficient of frequency based on the thickness of the piezoelectric layer 128. In example implementations, the compensation layer 310 can be formed using silicon dioxide (SiO₂), or some doped version thereof. Doped versions of silicon dioxide can include fluorine-doped silicon dioxide (e.g., SiOₓF_{y}) or carbon-doped silicon dioxide (e.g., SiOₓC_{y}). In some applications, the microacoustic resonator 126 may optionally include, for instance, an upper TCF compensation layer 312 disposed on the electrode structure 134 and the piezoelectric layer 128 to work cooperatively with the lower TCF compensation layer 310 to provide temperature compensation to the microacoustic resonator 126. In this regard, a thickness of the upper TCF compensation layer 312 may be dependent on a selected thickness of the lower TCF compensation layer 310. In some examples, one or both of the optional lower TCF compensation layer 310 and the upper TCF compensation layer 312 may be omitted to reduce cost of the microacoustic filter 124.

A passivation layer 314 can be disposed on the upper TCF compensation layer 312 or, in the absence of the upper TCF compensation layer 312, on the piezoelectric layer 128 and the electrode structure 134. In an example implementation, the passivation layer 314 is formed using silicon nitride (Si₃N₄). The passivation layer 314 can protect the underlying layer(s) from an external environment. The thickness of the passivation layer 314 can further be used to adjust the performance and/or frequency of the microacoustic resonator 126.

Sometimes the microacoustic filter 124 can comprise the microacoustic resonator 126 connected to other resonators associated with different layers than the microacoustic resonator 126. In other aspects, the microacoustic filter 124 can be implemented as multiple interconnected microacoustic resonators 126, each having the same layers shown in FIG. 3-1 (e.g., the piezoelectric layer 128, the electrode structure 134, and the high velocity layer 130).

FIG. 3-2 illustrates example Euler angles that define an orientation of the piezoelectric layer 128 relative to a crystalline structure of the material that forms the piezoelectric layer 128. In this example, the material that forms the piezoelectric layer 128 includes lithium niobate (LiNbO3) and/or lithium tantalate (LiTaO3). A first crystalline (X′) axis 326, a second crystalline (Y′) axis 328, and a third crystalline (Z′) axis 330 are fixed along crystallographic axes of a lithium niobate crystal. A first rotation 324-1 is applied to rotate the first crystalline X′ axis 326 and the second crystalline Y′ axis 328 about the third crystalline Z′ axis 330. In particular, the first rotation 324-1 rotates the first crystalline X′ axis 326 in a direction of the second crystalline Y′ axis 328. The angle associated with the first rotation 324-1 characterizes one of the Euler angles, which is represented by Euler angle lambda (λ) 332. The resulting rotated axes are represented by a new set of axes: an X″ axis 334, a Y″ axis 336, and a Z″ axis 338. As shown in FIG. 3-2, the third crystalline Z′ axis 330 remains unchanged by the first rotation 324-1 such that the third crystalline Z′ axis 330 is equal to the Z″ axis 338.

In a second rotation 324-2, the Y'′ axis 336 and the Z″ axis 338 are rotated about the X″ axis 334 by another Euler angle, which is represented by Euler angle mu (μ) 340. In this case, the Y″ axis 336 is rotated in the direction of the Z″ axis 338. The resulting rotated axes are represented by a new set of axes: an X″′ axis 342, a Y″′ axis 344, and a Z″′ axis 346. As shown in FIG. 3-2, the X″ axis 334 remains unchanged by the second rotation 324-2 such that the X″ axis 334 is equal to the X″′ axis 342.

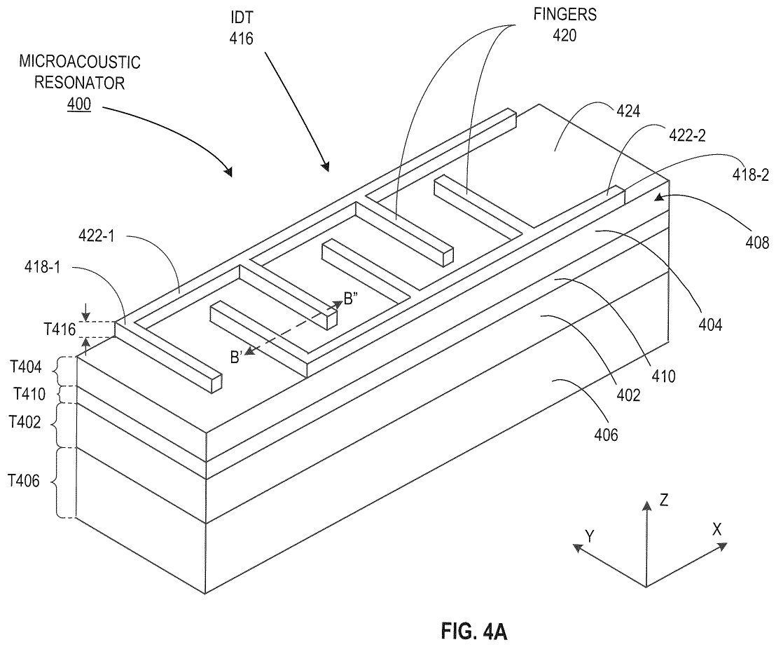

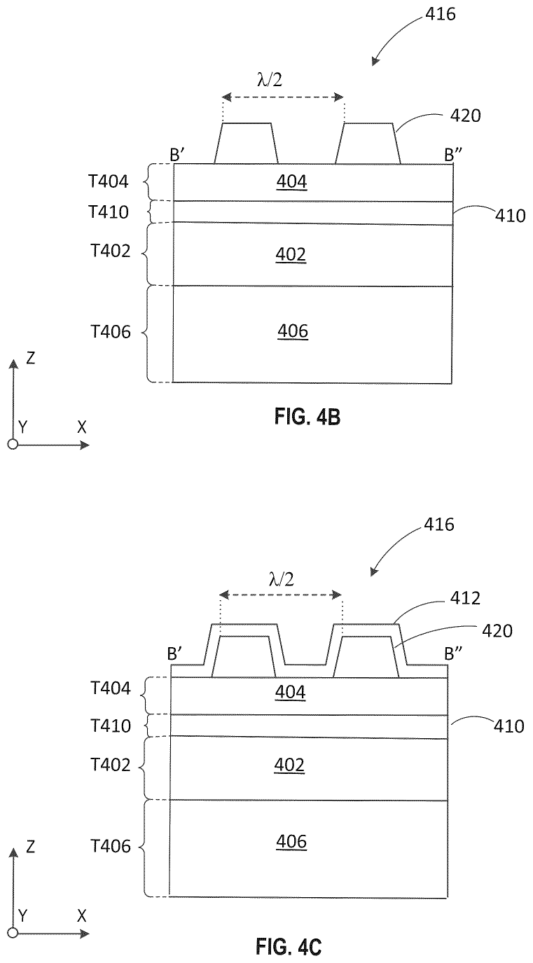

In a third rotation 324-3, the X″′ axis 342 and the Y″′ 344 axis are rotated about the Z″′ axis 346 by an additional Euler angle, which is represented by Euler angle theta (θ) 348. In this case, the X″′ axis 342 is rotated in the direction of the Y″′ axis 344. The resulting rotated axes are represented by a first filter (X) axis 350, a second filter (Y) axis 352, and a third filter (Z) axis 354, which respectively correspond to the first (X) axis, the second (Y) axis, and the third (Z) axis of FIGS. 4A-4C. As shown in FIG. 3-2, the Z″′ axis 346 remains unchanged by the third rotation 324-3 such that the Z″′ axis 346 is equal to the third filter Z axis 354. The microacoustic filter 124 is further described with respect to FIGS. 4A-4C.

FIG. 4A illustrates a three-dimensional perspective view of a first example of a microacoustic SAW resonator 400 (“microacoustic resonator 400”) with a high-velocity layer 402 between a piezoelectric layer 404 and a substrate 406 to confine acoustic energy in the piezoelectric layer 404 in a longitudinal mode. The microacoustic resonator 400 may be the microacoustic resonator 126 in FIGS. 1 and 3-1. Two examples of cross-sectional views of the microacoustic resonator 400 at cross-section B′-B″ are shown in FIGS. 4B and 4C. In the microacoustic resonator 400 in FIG. 4A, the term “longitudinal mode” refers to an acoustic wave where the local displacement in the material of the piezoelectric layer 404 is predominantly parallel to the direction of wave propagation, i.e., the X-axis direction. The longitudinal mode involves compressions and expansions along the path of an acoustic wave in the X-axis direction, which also creates additional out-of-plane displacement in the Z-axis direction.

The piezoelectric layer 404 having a crystal orientation that is excitable in the longitudinal mode, such as the examples of crystal orientation described with reference to FIG. 3-2, achieves resonant frequencies in the range of 3 GHz to 7 GHz and higher. There are some challenges to using the longitudinal mode, also known as the “longitudinal leaky mode”, in SAW devices, including significant attenuation and low Q factor due to the radiation of some types of waves through the bulk of the piezoelectric layer 404 in a direction of a thickness T404 of the piezoelectric layer 404 parallel to the Z-axis toward the substrate 406.

Including the high-velocity layer 402 in the microacoustic resonator 400 significantly reduces propagation of the waves and corresponding energy losses into the carrier substrate 132, providing a much higher Q factor. Additionally, the high-velocity layer 402 avoids the need for a multi-layer acoustic mirror or a suspended membrane structure while still minimizing losses into the substrate 406. In this manner, the high-velocity layer 402 reduces fabrication costs of the microacoustic resonator 400. In this context, the term “high-velocity layer” refers to a layer featuring a high acoustic velocity. The high-velocity layer 402 is formed of a high-velocity material 426 disposed on the substrate 406. The high-velocity material 426 has a first acoustic velocity 428 that is higher than a second acoustic velocity 430 of the piezoelectric layer 404. The second acoustic velocity 430 in the piezoelectric layer 404 is significantly affected by the elastic properties and density of the piezoelectric material 408 of which the piezoelectric layer 404 is formed. The first acoustic velocity 428 is determined by the density D of the high-velocity material 426 and a component C of a stiffness tensor in Voigt notation, which describes the material's response to stress in terms of strain. In the present context, a high-velocity layer is one having a ratio of the stiffness component C to the density D higher than the stiffness to density ratio of the other layers in which the longitudinal mode is excited. In the microacoustic resonator 400, the piezoelectric layer 404 is excited in the longitudinal mode and the excitation propagates into the high-velocity layer 402 and a TCF compensation layer 410 provided between the piezoelectric layer 404 and the high-velocity layer 402. A high-velocity layer is also identified by having a higher first acoustic velocity 428 than the second acoustic velocity 430 of the piezoelectric layer 404 and higher than the acoustic velocity of the TCF compensation layers 410, 412.

Materials that provide the stiffness of the high-velocity layer 402 include aluminum nitride (AlN), silicon carbide (SiC), and diamond. A high-velocity layer 402 formed of AlN provides a lower cost option compared to SiC and diamond. A high-velocity layer 402 of AlN may have a thickness T402 in the Z-axis direction equal to or greater than one wavelength Λ of the longitudinal mode at a resonant frequency. In some examples, the thickness T402 may be at least 1.5 microns (i.e., 1500 nanometers (nm)).

The TCF compensation layer 410 may be the lower TCF compensation layer 310 in FIG. 3-1. The TCF compensation layer 410 may be formed of materials including silicon dioxide (SiO2), without or with a fluorene dopant (e.g., SiOₓF_{y}). In the example in FIG. 4B, having a single TCF compensation layer, the TCF compensation layer 410 may have a thickness T410 in the Z-axis direction in a range of 30 nm to 100 nm, for example. Alternatively, in the example in FIG. 4C, having both a (lower) TCF compensation layer 410 and an optional (upper) TCF compensation layer 412, the (lower) TCF compensation layer 410 may have a thickness T410 in the Z-axis direction in a range of two percent (2%) to nine percent (9%) of the wavelength. In some examples, the thickness T410 may be in a range of 30 nm to 100 nm and the (upper) TCF compensation layer 412 may have a thickness T412 in the Z-axis direction in a range of 0.9 percent to 5.4 percent of the wavelength Λ. In some examples, the thickness T412 may be in a range of 10 nm to 60 nm. Examples of the materials and crystalline orientations from which the piezoelectric layer 404 may be formed are discussed above with reference to FIG. 3-2. A thickness T404 of the piezoelectric layer 404 may be in a range of nine percent (9%) to eighteen percent (18%) of the wavelength Λ. In some examples, the thickness T404 may be in a range of 100 nm to 200 nm, for example. The substrate 406 may be formed of any appropriate carrier substrate material, such as a silicon wafer.

The microacoustic SAW resonator 400 also includes an electrode structure 414, which can include one or more interdigital transducers (IDTs) 416. In FIG. 4A, the interdigital transducer 416 is shown to have two comb-shaped structures 418-1 and 418-2 with fingers 420 extending along a surface 424 of the piezoelectric layer 404 in a Y-axis direction from busbars 422-1 and 422-2 that extend in an X-axis direction along the surface 424. It should be understood that the X-axis, Y-axis, and Z-axis are perpendicular or orthogonal to each other. The fingers 420 are arranged in an interlocking manner in between the two busbars 422-1 and 422-2 of the interdigital transducer 416 (e.g., arranged in an interdigitated manner). In other words, the fingers 420 connected to the first busbar 422-1 extend towards the second busbar 422-2 but do not contact the second busbar 422-2. Likewise, the fingers 420 connected to the second busbar 422-2 extend towards the first busbar 422-1 but do not contact the first busbar 422-1.

In the X-axis direction along the busbars 422-1, 422-2, a portion of one finger 420 overlaps with a portion of an adjacent finger 420 in a central region, which may be referred to as the aperture, track, or active region where electric fields are produced between fingers 420 to cause an acoustic wave to form at least in this region of the piezoelectric layer 404.

In FIG. 4A, the surface 424 of the piezoelectric layer 404 is parallel to a plane formed by the X-axis and the Y-axis. The busbars 422-1, 422-2 of the interdigital transducer 416 are oriented to be parallel to the X-axis. The fingers 420 of the interdigital transducer 416 are oriented to extend parallel to the Y-axis. The fingers 420 generate an electric field in a direction that is substantially parallel to the X-axis. Due to the crystalline structure and orientation of the piezoelectric layer 404, the electric field excites the longitudinal mode within the piezoelectric layer 404. A resonant frequency of the acoustic waves excited in the piezoelectric layer 404 may depend on a pitch P or center-to-center spacing of the fingers 420 in the X-axis direction. For example, the pitch P of the fingers 420 may be determined as half of a wavelength (Λ) 440 (e.g., Λ/2) of the desired resonant frequency of the microacoustic resonator 400.

It should be noted that longitudinal mode of excitation of the piezoelectric layer 404 is highly sensitive to an IDT thickness T416 of the interdigital transducer 416, which must be in the range 0.06 to 0.08 of the wavelength Λ 440 of the resonant frequency of the microacoustic resonator 400 to attain the highest figure of merit in the microacoustic resonator 400. Higher and lower thicknesses cause high levels of attenuation, which is unsuitable for microacoustic filters. Materials from which the interdigital transducer 416 may be formed include aluminum (Al), copper (Cu), chromium (Cr), titanium (Ti), silicon (Si), and alloys thereof.

Using the piezoelectric effect, the acoustic wave forms within the piezoelectric layer 404 based on a time-varying input voltage signal in the interdigital transducer 416. Modified acoustic waves interact with the interdigital transducer 416 or another interdigital transducer within the electrode structure 414 (not shown in FIG. 4A) to generate a modified output voltage signal. In particular, the piezoelectric layer 404 generates an alternating electric field due to the mechanical stress generated by the acoustic wave. the output signal from the microacoustic resonator 400 is further processed by an arrangement of additional microacoustic resonators to produce a filtered radio-frequency signal that may be the filtered transmit signal 226, or the filtered receive signal 232 of FIG. 2.

It should be appreciated that while a certain number of fingers 420 are illustrated in FIG. 4A, the number of actual fingers and lengths and widths of the fingers and busbars may be different in an actual implementation. Such parameters depend on the particular application and desired filter characteristics. For example, as noted above, the pitch P of the fingers 420 is set according to a desired resonant frequency of the microacoustic resonator 400. In addition, the microacoustic resonator 400 can include multiple interconnected electrode structures 414, each including multiple interdigital transducers 416 to achieve a desired passband (e.g., multiple interconnected resonators or interdigital transducers 416 in series or parallel connections to form a desired filter transfer function).

The thicknesses of layers making up the microacoustic resonator 400 may also be expressed in relation to the wavelength Λ 440 of the resonant frequency in the longitudinal mode. For example, the thickness T402 of the piezoelectric layer 404 may be in a range of 0.09 to 0.18 (e.g., 9% to 18%) of the wavelength Λ 440. The thickness T410 of the (lower) TCF compensation layer 410 may be in a range of 0.02 to 0.09 (e.g., 2% to 9%) of the wavelength Λ 440. A combined thickness of the piezoelectric layer 404 and the TCF compensation layer 410 is less than about 0.22 (e.g., 22%) of the wavelength Λ 440. The thickness T402 of the fingers 420 of the interdigital transducer 416 may be in a range of 0.06 to 0.08(6 % to 8%) of the wavelength Λ 440. The thickness T412 of the optional (upper) TCF compensation layer 412 may be in a range of 0.009 to 0.054 (e.g., 0.9% to 5.4%) of the wavelength Λ 440.

FIG. 4B is a cross-sectional view of a first example of the microacoustic SAW resonator 400 at cross-section B′-B″. FIG. 4C is a cross-sectional view of a second example of the microacoustic resonator 400 at cross-section B′-B″. The first example of the microacoustic resonator 400 in FIG. 4B includes a (lower) TCF compensation layer 410 that may have a thickness in a range of 30 nm to 100 nm to compensate for the TCF of the piezoelectric layer 404. A total combined thickness of the piezoelectric layer 404 and the TCF compensation layer 410 is less than or equal to about 250 nm. The second example of the microacoustic resonator 400 in FIG. 4C includes both the (lower) TCF compensation layer 410 between the piezoelectric layer 404 and the high-velocity layer 402, and the (upper) TCF compensation layer 412 formed on the electrode structure 414 and the surface 424 of the piezoelectric layer 404. The (lower) TCF compensation layer 410 and the (upper) TCF compensation layer 412 provide a summed TCF compensation effect. With the additive effect of the (upper) TCF compensation layer 412, the thickness T410 of the TCF compensation layer 410 may be thinner in the second example in FIG. 4C than in the first example in FIG. 4B, in which the (lower) TCF compensation layer 410 provides all of the TCF compensation.

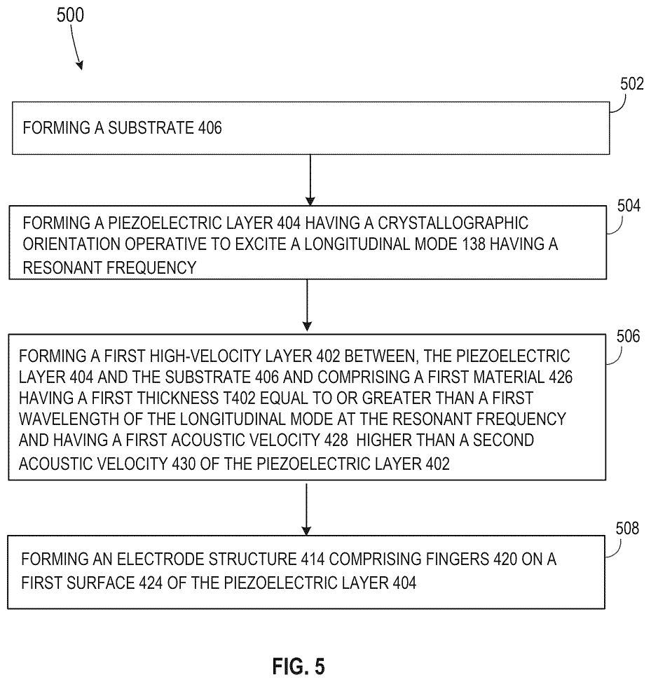

FIG. 5 is a flowchart of a method 500 of fabricating a microacoustic SAW resonator 400, the method comprising: forming a substrate 406 (block 502); forming a piezoelectric layer 404 having a crystallographic orientation operative to excite a longitudinal mode 138 having a resonant frequency (block 504); and forming a first high-velocity layer 402 between the piezoelectric layer 404 and the substrate 406 and comprising a first material 426 having a first thickness T402 equal to or greater than a first wavelength of the longitudinal mode at the resonant frequency and having a first acoustic velocity 428 higher than a second acoustic velocity 430 of the piezoelectric layer 404 (block 506). The method further comprises forming an electrode structure 414 comprising fingers 420 on a first surface 424 of the piezoelectric layer 404 (block 508).

Microacoustic filters may contain microacoustic SAW resonators in which the piezoelectric layers are excited in a longitudinal mode and in which a high-velocity layer is included to minimize irradiated energy propagation into the carrier substrate. Examples of such microacoustic filters, without limitation, include a set top box, an entertainment unit, a navigation device, a communications device, a fixed location data unit, a mobile location data unit, a global positioning system (GPS) device, a mobile phone, a cellular phone, a smart phone, a session initiation protocol (SIP) phone, a tablet, a phablet, a server, a computer, a portable computer, a mobile computing device, laptop computer, a wearable computing device (e.g., a smart watch, a health or fitness tracker, eyewear, etc.), a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, a portable digital video player, an automobile, a vehicle component, an avionics system, a drone, and a multicopter.

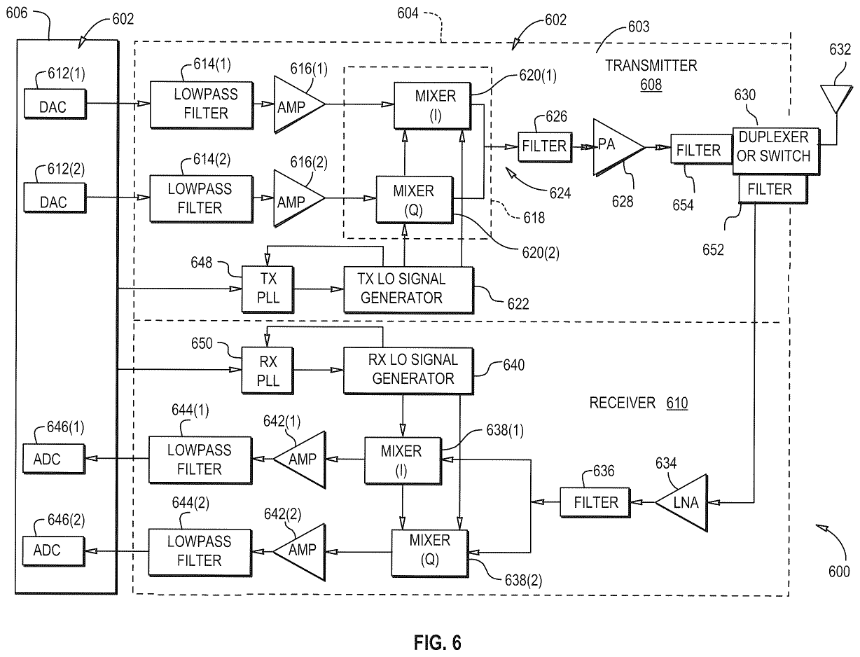

FIG. 6 illustrates an exemplary wireless communications device 600 that includes radio-frequency (RF) components formed from one or more integrated circuits (ICs) 602, wherein any of the ICs 602 may include microacoustic SAW resonators 400 including piezoelectric layers excited in a longitudinal mode and a high-velocity to confine irradiated energy from propagating into the carrier substrate, as shown in FIGS. 4A-4C. The wireless communications device 600 may include or be provided in any of the above-referenced devices, as examples. As shown in FIG. 6, the wireless communications device 600 includes a transceiver 604 and a data processor 606. The data processor 606 may include a memory to store data and program codes. The transceiver 604 includes a transmitter 608 and a receiver 610 that support bi-directional communications. In general, the wireless communications device 600 may include any number of transmitters 608 and/or receivers 610 for any number of communication systems and frequency bands. All or a portion of the transceiver 604 may be implemented on one or more analog ICs, RF ICs (RFICs), mixed-signal ICs, etc.

The transmitter 608 or the receiver 610 may be implemented with a super-heterodyne architecture or a direct-conversion architecture. In the super-heterodyne architecture, a signal is frequency-converted between RF and baseband in multiple stages, for example, from RF to an intermediate frequency (IF) in one stage and then from IF to baseband in another stage for the receiver 610. In the direct-conversion architecture, a signal is frequency-converted between RF and baseband in one stage. The super-heterodyne and direct-conversion architectures may use different circuit blocks and/or have different requirements. In the wireless communications device 600 in FIG. 6, the transmitter 608 and the receiver 610 are implemented with the direct-conversion architecture.

In the transmit path, the data processor 606 processes data to be transmitted and provides I and Q analog output signals to the transmitter 608. In the exemplary wireless communications device 600, the data processor 606 includes digital-to-analog converters (DACs) 612(1), 612(2) for converting digital signals generated by the data processor 606 into the I and Q analog output signals (e.g., I and Q output currents) for further processing.

Within the transmitter 608, lowpass filters 614(1), 614(2) filter the I and Q analog output signals, respectively, to remove undesired signals caused by the prior digital-to-analog conversion. Amplifiers (AMPs) 616(1), 616(2) amplify the signals from the lowpass filters 614(1), 614(2), respectively, and provide I and Q baseband signals. An upconverter 618 upconverts the I and Q baseband signals with I and Q transmit (TX) local oscillator (LO) signals through mixers 620(1), 620(2) from a TX LO signal generator 622 to provide an upconverted signal 624. A filter 626 filters the upconverted signal 624 to remove undesired signals caused by the frequency up-conversion as well as noise in a receive frequency band. A power amplifier (PA) 628 amplifies the upconverted signal 624 from the filter 626 to obtain the desired output power level and provides a transmit RF signal. The transmit RF signal is routed through a duplexer or switch 630 and transmitted via an antenna 632.

In the receive path, the antenna 632 receives signals transmitted by base stations and provides a received RF signal, which is routed through the duplexer or switch 630 and provided to a low noise amplifier (LNA) 634. The duplexer or switch 630 is designed to operate with a specific receive (RX)-to-TX duplexer frequency separation, such that RX signals are isolated from TX signals. The received RF signal is amplified by the LNA 634 and filtered by a filter 636 to obtain a desired RF input signal. Down-conversion mixers 638(1), 638(2) mix the output of the filter 636 with I and Q RX LO signals (i.e., LO_I and LO_Q) from an RX LO signal generator 640 to generate I and Q baseband signals. The I and Q baseband signals are amplified by AMPs 642(1), 642(2) and further filtered by lowpass filters 644(1), 644(2) to obtain I and Q analog input signals, which are provided to the data processor 606. In this example, the data processor 606 includes analog-to-digital converters (ADCs) 646(1), 646(2) for converting the analog input signals into digital signals to be further processed by the data processor 606.

In the wireless communications device 600 of FIG. 6, the TX LO signal generator 622 generates the I and Q TX LO signals used for frequency up-conversion, while the RX LO signal generator 640 generates the I and Q RX LO signals used for frequency down-conversion. Each LO signal is a periodic signal with a particular fundamental frequency. A TX phase-locked loop (PLL) circuit 648 receives timing information from the data processor 606 and generates a control signal used to adjust the frequency and/or phase of the TX LO signals from the TX LO signal generator 622. Similarly, an RX PLL circuit 650 receives timing information from the data processor 606 and generates a control signal used to adjust the frequency and/or phase of the RX LO signals from the RX LO signal generator 640.

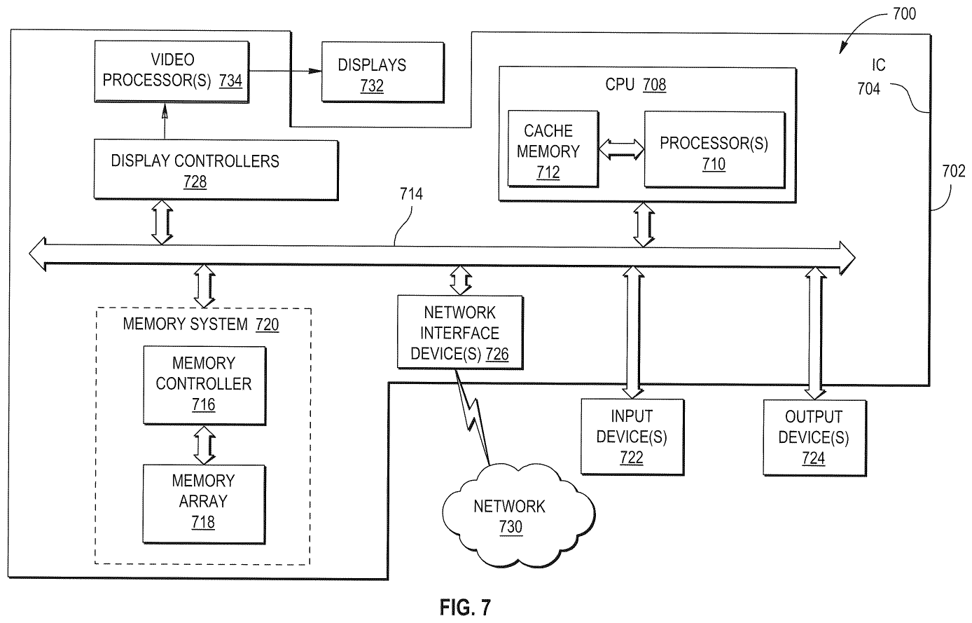

In this regard, FIG. 7 illustrates an example of a processor-based system 700 that can include microacoustic resonators 400 with piezoelectric layers excited in a longitudinal mode and a high-velocity to confined irradiated energy from propagating into the carrier substrate, as shown in FIGS. 4A-4C. The processor-based system 700 includes a central processing unit (CPU) 708 that includes one or more processors 710, which may also be referred to as CPU cores or processor cores. The CPU 708 may have cache memory 712 coupled to the CPU 708 for rapid access to temporarily stored data. The CPU 708 is coupled to a system bus 714 and can intercouple controller and controlled devices included in the processor-based system 700. As is well known, the CPU 708 communicates with these other devices by exchanging address, control, and data information over the system bus 714. For example, the CPU 708 can communicate bus transaction requests to a memory controller 716, as an example of a controlled device. Although not illustrated in FIG. 7, multiple system buses 714 could be provided, wherein each system bus 714 constitutes a different fabric.

Other controller and controlled devices can be connected to the system bus 714. As illustrated in FIG. 7, these devices can include a memory system 720 that includes the memory controller 716 and a memory array(s) 718, one or more input devices 722, one or more output devices 724, one or more network interface devices 726, and one or more display controllers 728, as examples. The input device(s) 722 can include any type of input device, including, but not limited to, input keys, switches, voice processors, etc. The output device(s) 724 can include any type of output device, including, but not limited to, audio, video, other visual indicators, etc. The network interface device(s) 726 can be any device configured to allow an exchange of data to and from a network 730. The network 730 can be any type of network, including, but not limited to, a wired or wireless network, a private or public network, a local area network (LAN), a wireless local area network (WLAN), a wide area network (WAN), a BLUETOOTH™ network, and the Internet. The network interface device(s) 726 can be configured to support any type of communications protocol desired.

The CPU 708 may also be configured to access the display controller(s) 728 over the system bus 714 to control information sent to one or more displays 732. The display controller(s) 728 sends information to the display(s) 732 to be displayed via one or more video processor(s) 734, which processes the information to be displayed into a format suitable for the display(s) 732. The display(s) 732 can include any type of display, including, but not limited to, a cathode ray tube (CRT), a liquid crystal display (LCD), a plasma display, a light emitting diode (LED) display, etc.

Those of skill in the art will further appreciate that the various illustrative logical blocks, modules, circuits, and algorithms described in connection with the aspects disclosed herein may be implemented as electronic hardware, instructions stored in memory or in another computer-readable medium wherein any such instructions are executed by a processor or other processing device, or combinations of both. The devices and components described herein may be employed in any circuit, hardware component, integrated circuit (IC), or IC chip, as examples. Memory disclosed herein may be any type and size of memory and may be configured to store any type of information desired. To clearly illustrate this interchangeability, various illustrative components, blocks, modules, circuits, and steps have been described above generally in terms of their functionality. How such functionality is implemented depends upon the particular application, design choices, and/or design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A processor may be a microprocessor, but in the alternative, the processor may be any conventional processor, controller, microcontroller, or state machine. A processor may also be implemented as a combination of computing devices (e.g., a combination of a DSP and a microprocessor, a plurality of microprocessors, one or more microprocessors in conjunction with a DSP core, or any other such configuration).

The aspects disclosed herein may be embodied in hardware and in instructions that are stored in hardware and may reside, for example, in Random Access Memory (RAM), flash memory, Read Only Memory (ROM), Electrically Programmable ROM (EPROM), Electrically Erasable Programmable ROM (EEPROM), registers, a hard disk, a removable disk, a CD-ROM, or any other form of computer readable medium known in the art. An exemplary storage medium is coupled to the processor such that the processor can read information from and write information to the storage medium. In the alternative, the storage medium may be integral to the processor. The processor and the storage medium may reside in an ASIC. The ASIC may reside in a remote station. In the alternative, the processor and the storage medium may reside as discrete components in a remote station, base station, or server.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flowchart diagrams may be subject to numerous different modifications as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples and designs described herein but is to be accorded the widest scope consistent with the principles and novel features disclosed herein.

Implementation examples are described in the following numbered clauses:
1. A microacoustic surface acoustic wave (SAW) resonator comprising:
   a substrate;
   a piezoelectric layer having a crystallographic orientation operative to excite a longitudinal mode having a resonant frequency;
   a first layer between the piezoelectric layer and the substrate and comprising a first material having a first thickness equal to or greater than a first wavelength of the longitudinal mode at the resonant frequency and a first acoustic velocity higher than a second acoustic velocity of the piezoelectric layer; and
   an electrode structure comprising fingers on a first surface of the piezoelectric layer.
2. The microacoustic SAW resonator of clause 1, wherein the first layer comprises aluminum nitride (AlN).
3. The microacoustic SAW resonator of clause 1 or clause 2, further comprising a second layer disposed between the piezoelectric layer and the first layer, wherein:
   the second layer comprises a second material configured to offset a temperature coefficient of frequency (TCF) of the piezoelectric layer; and
   the first acoustic velocity of the first layer is higher than a third acoustic velocity of the second layer.
4. The microacoustic SAW resonator of clause 3, wherein the second material of the second layer comprises silicon dioxide (SiO2).
5. The microacoustic SAW resonator of clause 3 or clause 4, further comprising a second layer disposed between the piezoelectric layer and the first layer, wherein:
   the second layer has a second thickness in a range from two percent (2%) to nine percent (9%) of the first wavelength of an acoustic wave on the first surface of the piezoelectric layer at the resonant frequency of the piezoelectric layer in the longitudinal mode.
6. The microacoustic SAW resonator of clause 5, wherein the piezoelectric layer has a third thickness in a range from one hundred (100) to two hundred (200) nanometers (nm).
7. The microacoustic SAW resonator of clause 5, wherein the piezoelectric layer has a third thickness in a range from nine percent (9%) to eighteen percent (18%) of the first wavelength of an acoustic wave on the first surface of the piezoelectric layer at the resonant frequency of the piezoelectric layer in the longitudinal mode.
8. The microacoustic SAW resonator of clause 7, wherein a combined thickness of the second thickness of the second layer and the third thickness of the piezoelectric layer is less than two hundred and fifty (250) nanometers (nm).
9. The microacoustic SAW resonator of clause 7, wherein a combined thickness of the second thickness of the second layer and the third thickness of the piezoelectric layer is less than twenty two percent (22%) of the first wavelength of the acoustic wave on the first surface of the piezoelectric layer at the resonant frequency of the piezoelectric layer in the longitudinal mode.
10. The microacoustic SAW resonator of any of clause 1 to clause 9, wherein the fingers of the electrode structure have a fourth thickness in a range from six percent (6%) to eight percent (8%) of the first wavelength of an acoustic wave on the first surface of the piezoelectric layer at the resonant frequency of the piezoelectric layer in the longitudinal mode.
11. The microacoustic SAW resonator of clause 10, wherein the fingers of the electrode structure have the fourth thickness in a range from seven percent (7%) to eight percent (8%) of the first wavelength of the acoustic wave on the first surface of the piezoelectric layer at the resonant frequency of the piezoelectric layer in the longitudinal mode.
12. The microacoustic SAW resonator of any of clause 3 to clause 11, further comprising a third layer disposed on the electrode structure and the first surface of the piezoelectric layer, wherein:
   the third layer comprises a third material configured to offset the temperature coefficient of frequency (TCF) of the piezoelectric layer; and
   the third layer has a fifth thickness in a range of ten (10) to sixty (60) nanometers (nm).
13. The microacoustic SAW resonator of any of clause 3 to clause 11, further comprising a third layer disposed on the electrode structure and the first surface of the piezoelectric layer, wherein:
   the third layer comprises a third material configured to offset the temperature coefficient of frequency (TCF) of the piezoelectric layer; and
   the third layer has a fifth thickness in a range of 0.9% to 5.4% of the first wavelength of an acoustic wave on the first surface of the piezoelectric layer at the resonant frequency of the piezoelectric layer in the longitudinal mode.
14. The microacoustic SAW resonator of clause 1, wherein:
   the piezoelectric layer comprises lithium niobate (LiNbO³);
   the fingers of the electrode structure extend in a first direction of a first axis and substantially perpendicular to a second axis;
   a third axis is perpendicular to the first axis and the second axis;
   an orientation of the first axis, the second axis, and the third axis is relative to a crystalline structure of the piezoelectric layer as defined by Euler angles lambda, mu, and theta; and
   the crystallographic orientation of the lithium niobate has a value of the Euler angle lambda being approximately 90°, a value of the Euler angle mu being approximately 90°, and a value of the Euler angle theta being approximately 42°, or at least one symmetrical equivalent thereof.
15. The microacoustic SAW resonator of clause 1, wherein:
   the piezoelectric layer comprises lithium niobate (LiNbO³);
   the fingers of the electrode structure extend in a first direction of a first axis and substantially perpendicular to a second axis;
   a third axis is perpendicular to the first axis and the second axis;
   an orientation of the first axis, the second axis, and the third axis is relative to a crystalline structure of the piezoelectric layer as defined by Euler angles lambda, mu, and theta; and
   the crystallographic orientation of the lithium niobate has a value of the Euler angle lambda being approximately 0°, a value of the Euler angle mu being approximately 32.5°, and a value of the Euler angle theta being approximately 90°, or at least one symmetrical equivalent thereof.
16. The microacoustic SAW resonator of clause 1, wherein:
   the piezoelectric layer comprises lithium niobate (LiNbO³);
   the fingers of the electrode structure extend in a first direction of a first axis and substantially perpendicular to a second axis;
   a third axis is perpendicular to the first axis and the second axis;
   an orientation of the first axis, the second axis, and the third axis is relative to a crystalline structure of the piezoelectric layer as defined by Euler angles lambda, mu, and theta; and
   the crystallographic orientation of the lithium niobate has a value of the Euler angle lambda being approximately 0°, a value of the Euler angle mu being approximately −50°, and a value of the Euler angle theta being approximately 50°, or at least one symmetrical equivalent thereof.
17. The microacoustic SAW resonator of any of clause 1 to clause 16, wherein the resonant frequency of the piezoelectric layer in the longitudinal mode is between three (3) gigahertz (GHz) and approximately seven (7) GHz.
18. The microacoustic SAW resonator of any of clause 1 to clause 18, wherein the longitudinal mode comprises a longitudinal leaky mode.
19. An apparatus comprising:
   a transceiver circuit comprising:
      a microacoustic SAW resonator, comprising:
         a substrate;
         a piezoelectric layer having a crystallographic orientation operative to excite a longitudinal mode having a resonant frequency;
         a first layer between the piezoelectric layer and the substrate and comprising a first material having a first thickness equal to or greater than a first wavelength of the longitudinal mode at the resonant frequency and a first acoustic velocity higher than a second acoustic velocity of the piezoelectric layer; and
         an electrode structure comprising fingers on a first surface of the piezoelectric layer; and
   an antenna coupled to the transceiver circuit.
20. A method of fabricating a microacoustic SAW resonator, the method comprising:
   forming a substrate;
   forming a piezoelectric layer having a crystallographic orientation operative to excite a longitudinal mode having a resonant frequency;
   forming a first layer between the piezoelectric layer and the substrate and comprising a first material having a first thickness equal to or greater than a first wavelength of the longitudinal mode at the resonant frequency and a first acoustic velocity higher than a second acoustic velocity of the piezoelectric layer; and
   forming an electrode structure comprising fingers on a first surface of the piezoelectric layer.

What is claimed is:

1. A microacoustic surface acoustic wave (SAW) resonator comprising:
a substrate;
a piezoelectric layer having a crystallographic orientation operative to excite a longitudinal mode having a resonant frequency;
a first layer between the piezoelectric layer and the substrate and comprising a first material having a first thickness equal to or greater than a first wavelength of the longitudinal mode at the resonant frequency and a first acoustic velocity higher than a second acoustic velocity of the piezoelectric layer; and
an electrode structure comprising fingers on a first surface of the piezoelectric layer.

2. The microacoustic SAW resonator of claim 1, wherein the first layer comprises aluminum nitride (AlN).

3. The microacoustic SAW resonator of claim 1, further comprising a second layer disposed between the piezoelectric layer and the first layer, wherein:
the second layer comprises a second material configured to offset a temperature coefficient of frequency (TCF) of the piezoelectric layer; and
the first acoustic velocity of the first layer is higher than a third acoustic velocity of the second layer.

4. The microacoustic SAW resonator of claim 3, wherein the second material of the second layer comprises silicon dioxide (SiO2).

5. The microacoustic SAW resonator of claim 3, further comprising a second layer disposed between the piezoelectric layer and the first layer, wherein:
the second layer has a second thickness in a range from two percent (2%) to nine percent (9%) of the first wavelength of an acoustic wave on the first surface of the piezoelectric layer at the resonant frequency of the piezoelectric layer in the longitudinal mode.

6. The microacoustic SAW resonator of claim 5, wherein the piezoelectric layer has a third thickness in a range from one hundred (100) to two hundred (200) nanometers (nm).

7. The microacoustic SAW resonator of claim 5, wherein the piezoelectric layer has a third thickness in a range from nine percent (9%) to eighteen percent (18%) of the first wavelength of an acoustic wave on the first surface of the piezoelectric layer at the resonant frequency of the piezoelectric layer in the longitudinal mode.

8. The microacoustic SAW resonator of claim 7, wherein a combined thickness of the second thickness of the second layer and the third thickness of the piezoelectric layer is less than two hundred and fifty (250) nanometers (nm).

9. The microacoustic SAW resonator of claim 7, wherein a combined thickness of the second thickness of the second layer and the third thickness of the piezoelectric layer is less than twenty two percent (22%) of the first wavelength of the acoustic wave on the first surface of the piezoelectric layer at the resonant frequency of the piezoelectric layer in the longitudinal mode.

10. The microacoustic SAW resonator of claim 1, wherein the fingers of the electrode structure have a fourth thickness in a range from six percent (6%) to eight percent (8%) of the first wavelength of an acoustic wave on the first surface of the piezoelectric layer at the resonant frequency of the piezoelectric layer in the longitudinal mode.

11. The microacoustic SAW resonator of claim 10, wherein the fingers of the electrode structure have the fourth thickness in a range from seven percent (7%) to eight percent (8%) of the first wavelength of the acoustic wave on the first surface of the piezoelectric layer at the resonant frequency of the piezoelectric layer in the longitudinal mode.

12. The microacoustic SAW resonator of claim 3, further comprising a third layer disposed on the electrode structure and the first surface of the piezoelectric layer, wherein:
the third layer comprises a third material configured to offset the temperature coefficient of frequency (TCF) of the piezoelectric layer; and
the third layer has a fifth thickness in a range of ten (10) to sixty (60) nanometers (nm).

13. The microacoustic SAW resonator of claim 3, further comprising a third layer disposed on the electrode structure and the first surface of the piezoelectric layer, wherein:
the third layer comprises a third material configured to offset the temperature coefficient of frequency (TCF) of the piezoelectric layer; and
the third layer has a fifth thickness in a range of 0.9% to 5.4% of the first wavelength of an acoustic wave on the first surface of the piezoelectric layer at the resonant frequency of the piezoelectric layer in the longitudinal mode.

14. The microacoustic SAW resonator of claim 1, wherein:
the piezoelectric layer comprises lithium niobate (LiNbO³);
the fingers of the electrode structure extend in a first direction of a first axis and substantially perpendicular to a second axis;
a third axis is perpendicular to the first axis and the second axis;
an orientation of the first axis, the second axis, and the third axis is relative to a crystalline structure of the piezoelectric layer as defined by Euler angles lambda, mu, and theta; and
the crystallographic orientation of the lithium niobate has a value of the Euler angle lambda being approximately 90°, a value of the Euler angle mu being approximately 90°, and a value of the Euler angle theta being approximately 42°, or at least one symmetrical equivalent thereof.

15. The microacoustic SAW resonator of claim 1, wherein:
the piezoelectric layer comprises lithium niobate (LiNbO³);
the fingers of the electrode structure extend in a first direction of a first axis and substantially perpendicular to a second axis;
a third axis is perpendicular to the first axis and the second axis;
an orientation of the first axis, the second axis, and the third axis is relative to a crystalline structure of the piezoelectric layer as defined by Euler angles lambda, mu, and theta; and
the crystallographic orientation of the lithium niobate has a value of the Euler angle lambda being approximately 0°, a value of the Euler angle mu being approximately 32.5°, and a value of the Euler angle theta being approximately 90°, or at least one symmetrical equivalent thereof.

16. The microacoustic SAW resonator of claim 1, wherein:
the piezoelectric layer comprises lithium niobate (LiNbO³);
the fingers of the electrode structure extend in a first direction of a first axis and substantially perpendicular to a second axis;
a third axis is perpendicular to the first axis and the second axis;
an orientation of the first axis, the second axis, and the third axis is relative to a crystalline structure of the piezoelectric layer as defined by Euler angles lambda, mu, and theta; and
the crystallographic orientation of the lithium niobate has a value of the Euler angle lambda being approximately 0°, a value of the Euler angle mu being approximately−50°, and a value of the Euler angle theta being approximately 50°, or at least one symmetrical equivalent thereof.

17. The microacoustic SAW resonator of claim 1, wherein the resonant frequency of the piezoelectric layer in the longitudinal mode is between three (3) gigahertz (GHz) and approximately seven (7) GHz.

18. The microacoustic SAW resonator of claim 1, wherein the longitudinal mode comprises a longitudinal leaky mode.

19. An apparatus comprising:
a transceiver circuit comprising:
a microacoustic SAW resonator, comprising:
a substrate;
a piezoelectric layer having a crystallographic orientation operative to excite a longitudinal mode having a resonant frequency;
a first layer between the piezoelectric layer and the substrate and comprising a first material having a first thickness equal to or greater than a first wavelength of the longitudinal mode at the resonant frequency and a first acoustic velocity higher than a second acoustic velocity of the piezoelectric layer; and
an electrode structure comprising fingers on a first surface of the piezoelectric layer; and
an antenna coupled to the transceiver circuit.

20. A method of fabricating a microacoustic SAW resonator, the method comprising:
forming a substrate;
forming a piezoelectric layer having a crystallographic orientation operative to excite a longitudinal mode having a resonant frequency;
forming a first layer between the piezoelectric layer and the substrate and comprising a first material having a first thickness equal to or greater than a first wavelength of the longitudinal mode at the resonant frequency and a first acoustic velocity higher than a second acoustic velocity of the piezoelectric layer; and
forming an electrode structure comprising fingers on a first surface of the piezoelectric layer.
